(19) United States
(12) Patent Application Publication
(10) Pub. No.: US 2025/0362870 A1
(43) Pub. Date: Nov. 27, 2025

(54) SPARSITY-AWARE ZERO SKIPPING FOR COMPUTE-IN-MEMORY CIRCUITS

(71) Applicant: Taiwan Semiconductor Manufacturing Company, Ltd., Hsinchu (TW)

(72) Inventors: Je-Min Hung, Hsinchu (TW); Haruki Mori, Hsinchu (TW); Chia-Fu Lee, Hsinchu (TW); Hidehiro Fujiwara, Hsinchu (TW)

(73) Assignee: Taiwan Semiconductor Manufacturing Company, Ltd., Hsinchu (TW)

(21) Appl. No.: 19/292,364

(22) Filed: Aug. 6, 2025

Related U.S. Application Data
(63) Continuation of application No. 18/405,921, filed on Jan. 5, 2024.
(60) Provisional application No. 63/578,203, filed on Aug. 23, 2023.
(60) Provisional application No. 63/613,254, filed on Dec. 21, 2023.

(51) Int. Cl. G06F 7/499

(52) U.S. Cl. CPC G06F 7/49915

(57) ABSTRACT

A system, circuit, and method of operation of the system and circuit are disclosed. In one aspect, a device includes a computation circuit, a memory array, and a controller. The controller can determine that one or more input data bits to the computation circuit or one or more memory bits provided from the memory array are all in a first logic state. In response to determining that the one or more input data bits or the one or more memory bits are all in the first logic state, the controller can generate a control signal to disable at least one component of the computation circuit.

### CROSS-REFERENCES TO RELATED APPLICATION

This application is a continuation of and claims priority to U.S. patent application Ser. No. 18/405,921, filed Jan. 5, 2024, which claims the benefit of and priority both to U.S. Provisional Application No. 63/578,203, filed Aug. 23, 2023, and to U.S. Patent App. No. 63/613,254, filed Dec. 21, 2023, the disclosures of each of which are incorporated herein by reference in their entireties.

### BACKGROUND

An integrated circuit (IC) can contain a variety of hardware circuit devices or types of logic, including FPGAs, application-specific integrated circuits (ASICs), logic gates, registers, or transistors, in addition to various interconnections between the circuit devices. The IC can be manufactured using or composed of semiconductor materials, for instance, as part of electronic devices, such as computers, portable devices, smartphones, internet of thing (IoT) devices, etc. Developments and increasing complexity of the ICs have prompted increased demands for higher computational efficiency and speed. More specifically, the ICs can be configurable and/or programmable to perform computations in sequences or variations desired by the manufacturer, developer, technician, or programmer, among others.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic block diagram of an example compute-in-memory (CIM) circuit that implements example zero-skipping, in accordance with some embodiments of the present disclosure.

FIG. 2 illustrates example waveforms of signals that propagate through the example CIM circuit shown in FIG. 1, in accordance with some embodiments of the present disclosure.

FIG. 3 illustrates an example processing system that implements zero-skipping using a controller, in accordance with some embodiments of the present disclosure.

FIG. 4 illustrates an example CIM circuit that implements zero-skipping for memory output data, in accordance with some embodiments of the present disclosure.

FIG. 5 illustrates example waveforms of signals that propagate through the example CIM circuit shown in FIG. 4, in accordance with some embodiments of the present disclosure.

FIG. 6 illustrates an example CIM multiplication circuit that implements zero-skipping for memory output data, in accordance with some embodiments of the present disclosure.

FIG. 7 illustrates example waveforms of signals that propagate through the example CIM circuit shown in FIG. 6, in accordance with some embodiments of the present disclosure.

FIG. 8 illustrates an example CIM multiplication circuit that implements zero-skipping via gating of a clock signal, in accordance with some embodiments of the present disclosure.

FIG. 9 illustrates example waveforms of signals that propagate through the example CIM circuit shown in FIG. 8, in accordance with some embodiments of the present disclosure.

FIG. 10 illustrates another example processing system that implements zero-skipping using a controller and clock gating, in accordance with some embodiments of the present disclosure.

FIG. 11 illustrates an example CIM multiplication circuit that implements zero-skipping via gating of a power signal, in accordance with some embodiments of the present disclosure.

FIG. 12 illustrates example waveforms of signals that propagate through the example CIM circuit shown in FIG. 11, in accordance with some embodiments of the present disclosure.

FIG. 13 illustrates an example CIM multiplication circuit that implements zero-skipping via gating of a power signal based on memory output signals, in accordance with some embodiments of the present disclosure.

FIG. 14 illustrates a flowchart of an example method to operate the disclosed CIM circuits described herein, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Compute-in-memory (CIM) devices include circuits that combine memory and computation in the same physical location. By placing computational circuitry directly within memory storage circuits, data doesn't need to travel as far and therefore reduces computational latency and overall power consumption. Computational circuitry can include accumulator devices, which may include adder circuits and shifting circuits that efficiently process memory information for a variety of use-cases, including machine-learning, matrix multiplications, or general parallel computing.

These circuits operate in connection with input data and data retrieved from memory devices to efficiently process compute operations without suffering from memory bandwidth issues. Conventional compute-in-memory circuits include circuitry are inefficient because they do not compensate for “zero” input data. For example, in a multiplication circuit, when at least one input of two operands is zero, the output is to be zero. The energy efficiency of conventional circuits is therefore because the multiplication results of such computations do not contribute to the final output (which is, e.g., zero), but power is still consumed to perform the computation.

The systems and methods described herein address these inefficiencies by implementing a “zero detection” circuit in connection with CIM circuits. The zero-detection circuit can detect when at least one operand of certain mathematical operations is zero, and automatically disables one or more components of the CIM circuit to improve overall power consumption. The zero-detection circuit also sets the resulting output for the mathematical operation to zero, effectively bypassing the energy-consuming mathematical computation circuits.

The techniques described herein can be used to detect logical zeros on input data as well as data provided by memory devices of the CIM circuits, and automatically skip operations such as memory access, multiplication, and mantissa shift for both integer and floating point mathematical operations. In doing so, the zero detection circuits described herein reduce power consumption of CIM circuits while preserving mathematical accuracy and computational throughput. Disabling of components may include generating a disable signal, clock gating, or power gating of one or more circuits, as described herein.

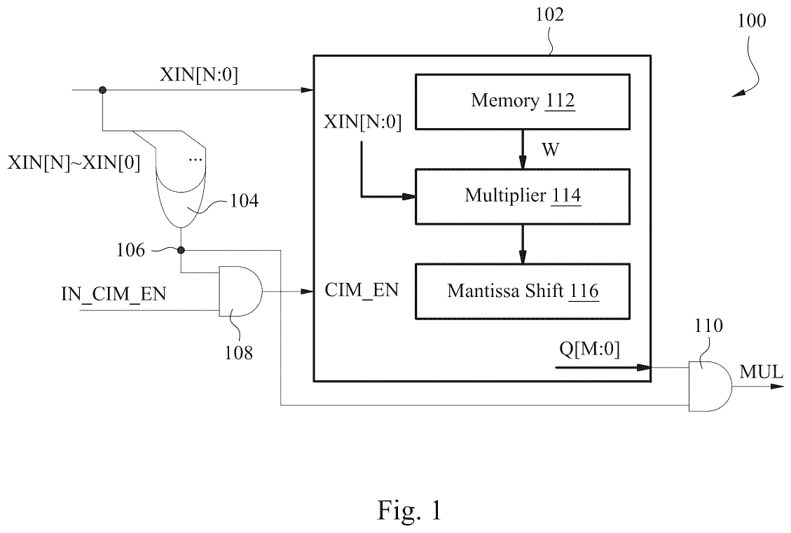

Referring to FIG. 1, illustrated is a schematic block diagram 100 of an example CIM circuit 102 that implements example zero-skipping, in accordance with some embodiments of the present disclosure. Each of the components shown in the CIM circuit 102 may receive power from one or more voltage sources. The CIM circuit 102 may include one or more logic gates and sub-circuits, each of which may be constructed from one or more logic gates. Logic gates are electronic devices that perform logical operations on one or more input signals to produce a single output signal.

Various embodiments of the circuits and logic gates that implement the CIM circuit 102 may include various transistors. The transistors described herein may have a certain type (n-type or p-type), but embodiments are not limited thereto. The transistors can be any suitable type of transistor including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

The zero-skipping techniques described herein may be implemented via one or more logic gates, and may be used to detect input data or data produced by a memory circuit that are all in a first logic state (e.g., a logic zero state, logic low state, etc.). As shown, the example CIM circuit includes a memory device 112, a multiplier device 114, and a mantissa shift block 116. Each of these devices, blocks, and circuits may receive power from one or more power sources and may receive signals from other circuits, logic components, or devices.

The memory device 112 may be any type of computer-readable memory device that may be implemented in a CIM circuit, including but not limited to static random-access-memory (SRAM), dynamic random-access-memory (DRAM), or flash memory, among others. The memory 112 may be coupled to one or more data input signals (e.g., for writing data to the memory), and include one or more output signals that provide data stored in the memory device 112 during a read operation. The memory device 112 can receive one or more control signals to coordinate read, write, or other operations, such as read enable signals, write enable signals, data input signals, address signals, clock signals, and/or power signals. In this example, the output of the memory device 112, shown here as the “weights (W),” is provided as input to the multiplier device 114. The data stored in the memory device 112 may include integer data and/or floating point data. The memory device 112 can provide any number of output bits to the multiplier device 114.

The multiplier device 114 is shown as receiving an output of the memory device 112, which may be provided as part of a read operation. The multiplier device 114 is shown as receiving input data, represented as the input bits XIN. In this example, the input bits include N+1 bits of input data. The data bits W provided by the memory device 112 may have the same number of bits or a different number of bits than the input data XIN. The multiplier device 114 may receive any number of corresponding control signals to control the operations of the multiplier device 114. In some implementations, the multiplier device 114 may receive an operation signal that indicates whether the data received by the multiplier device 114 is floating point data or integer data, to control whether a floating-point multiplication or an integer multiplication operation is performed.

The multiplier device 114 can include any number of logic devices, circuits, transistors, or components to implement binary multiplication operations. The multiplier 114 may include any type of multiplier suitable for the CIM circuit 102, the memory device 112, and the input data XIN. An output product of the multiplication device 114 is shown as provided as input to the mantissa shift device 116. The mantissa shift device 116 can be used to perform bit-shifting operations, e.g., for floating point multiplication. The mantissa shift device 116 can include any number of logic devices, circuits, transistors, or components to implement mantissa shifting operations. The output of the mantissa shift device 116 is shown here as the output data bits Q. The output data bits Q is shown here as include M+1 bits of data.

In the example implementation shown in the diagram 100, logic devices are used to implement zero detection to perform energy efficiency. As shown, the one or more first logic devices 104 are used to detect whether the input data XIN are all in a first logic state (e.g., logic zero, logic low, etc.). To do so, the one or more first logic devices 104 may include logical OR gates. For example, the one or more first logic devices 104 may include any number of logic gates, transistors, or devices to implement an N+1 input OR gate, in some implementations. The one or more first logic devices 104 are shown as receiving all bits of the input data XIN as input and generating a zero-detection signal 106. The zero-detection signal 106 of the one or more first logic devices 104 may be in a second logic state (e.g., logic high, logic one, etc.) when any of the bits of the input data XIN is in the second logic state. When all of the bits of the input data XIN are in the first logic state (e.g., logic low, logic zero), the zero-detection signal 106 generated by the one or more first logic device 104 is in the first logic state.

The zero-detection signal 106 is provided as input to a second logic device 108. In this example, the second logic device 108 is implemented as a logic AND gate. The second logic device 108 is shown as receiving the zero-detection signal 106 and an enable signal for the CIM circuit 102 (shown here as IN_CIM_EN). The IN_CIM_EN signal may be a control signal that controls whether the CIM circuit 102 is enabled (e.g., processing the XIN data and the data W retrieved from the memory device 112). The second logic device 108 generates an output enable signal CIM_EN that is provided to an enable input of the CIM circuit 102. In this example, when both the zero detection signal 106 and the input enable signal IN_CIM_EN are both in the second logic state (e.g., logic high, logic one, etc.), the output enable signal CIM_EN is provided in the second logic state, and the CIM circuit 102 is enabled and operates on the input data XIN and the memory data W of the memory device 112, as shown.

When one or more of the zero detection signal 106 or the enable signal CIM_EN are in the first logic state, the output enable signal CIM_EN is provided to the CIM circuit 102 in the first logic state, causing the CIM circuit 102 to be disabled. For example, the CIM circuit 102 may include logic gates, transistors, or other circuits that prevent or minimize power consumption of the CIM circuit 102 when input enable signal is in the first logic state. For example, one or more of the multiplier device 114 or the mantissa shift device 116 are configured in a disabled state (e.g., minimizing power consumption and not processing data). In some implementations, circuitry for reading and/or retrieving data from the memory device 112 may also be disabled when the input enable signal for the CIM circuit 102, generated by the second logic device 108, is in the first logic state.

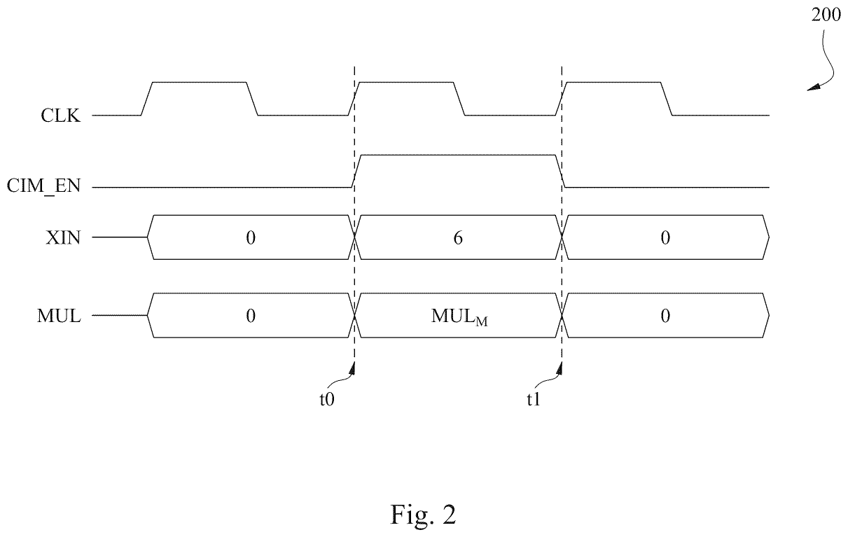

To control the output data, the zero-detection signal 106 is provided as input to one or more third logic devices 110. In this example, the one or more third logic devices 110 include one or more logic AND gates. In some implementations, the one or more third logic devices 110 each receive the zero-detection signal 106 and a respective output bit of the output data Q [M: 0]. The zero-detection signal 106, which operates as a zero detection signal, is used by the one or more third logic devices 110 to generate output data MUL. The output data MUL can include the same number of bits as the output data Q[M:0] (e.g., M+1 bits). When the zero detection signal 106 is in the first logic state (e.g., logic low, logic zero), which indicates that the input data XIN is all in the first logic state, the one or more third logic devices 110 causes each bit of the output data MUL to be in the first logic state, while the CIM circuit 102 is disabled by the signal generated via the second logic device 108. This effectively disables the CIM circuit 102 while setting the output data MUL for the circuit to be in the first logic state, using the one or more third logic devices 110 to bypass the CIM circuit 102 to produce each bit of the output data MUL. Example waveforms showing the operation of the CIM circuit 102 in connection with the one or more first logic devices 104, the second logic device 108, and the one or more third logic devices 110 is shown in FIG. 2.

Referring to FIG. 2 in the context of the components described in connection with FIG. 1, illustrated are example waveforms 200 of signals that propagate through the example CIM circuit 102 shown in FIG. 1, in accordance with some embodiments of the present disclosure. As shown, in this example, an input clock signal CLK continuously alternates and is unaffected by the logic state of the input data XIN. As shown, before time t0, the input data XIN is equal to zero (e.g., all bits in the first logic state, logic low, logic zero). As a result, the one or more first logic devices 104 and the second logic device 108 generate the output enable signal CIM_EN in the first logic state (e.g., logic low, logic zero). Likewise, the output data MUL, generated by the one or more third logic devices 110, is in the first logic state (all bits set to zero).

As shown, after time t0 occurs, the input data XIN has changed to a non-zero value (e.g., not all bits in the first logic state), shown here as the value of “6.” As a result, the one or more first logic devices 104 and the second logic device 108 generate the output enable signal CIM_EN in the second logic state (e.g., logic high, logic one). The output data MUL is equal to the product of the input data XIN and data retrieved from the memory device 112, as described herein. In this example, the product is shown as “MUL_{M},” and is generated by the one or more third logic devices 110, as described herein. At time t1, the input data XIN changes back to the zero value, and the CIM circuit 102 is disabled as described herein.

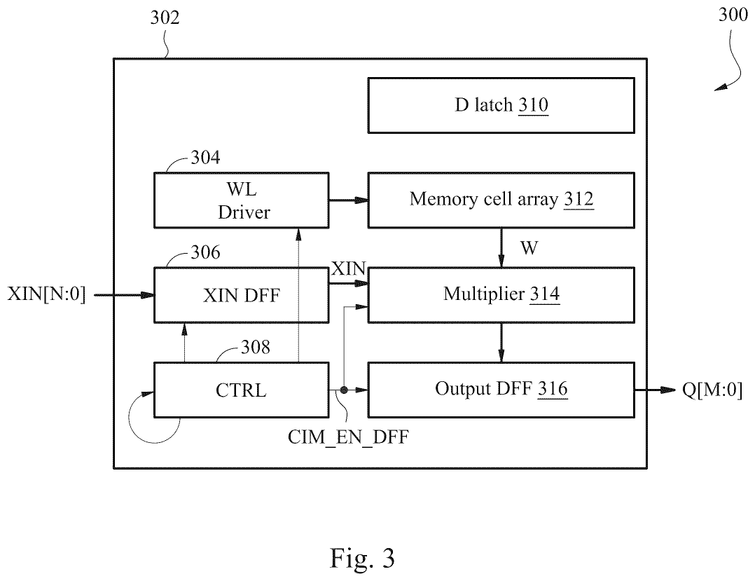

Referring to FIG. 3, illustrated is an example processing system 300 including a CIM circuit 302 that implements zero-skipping using a controller 308, in accordance with some embodiments of the present disclosure. Various embodiments of the circuits and logic gates that implement the processing system 300 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 302 of the processing system 300 can be similar to, and can include any of the structure, components, or functionality of, the CIM circuit 102 described in connection with FIG. 1. For example, the controller 308 may include any of the one or more first logic devices 104, the second logic device 108, and/or the one or more second logic devices 110. The CIM_EN_DFF signal generated by the controller 308 is provided to one or more components (e.g., the of the word-line (WL) driver 304, input flip-flops 306, the multiplier device 314, and the output flip-flops 316) of the CIM circuit 302 to selectively disable said components when all bits of the input data XIN are in the first logic state, as described herein.

The memory cell array 312 may be similar to, and include any of the components, structure, or functionality of, the memory array 112 of FIG. 1. For example, the memory cell array 312 may include an array of memory cells, and may include any type of suitable memory device (e.g., SRAM, DRAM, flash memory, etc.). The memory array 312 is shown as being coupled to one or more data latches 310. The data input latches 310 can receive data from one or more write lines to write data to one or more cells of the memory cell array 312. In some implementations, each data input latch 310 provides data to at least one respective cell in the memory cell array 312.

The WL driver 304 can include logic gates, circuits, and/or transistors that drive the word lines of the memory cell array 312. For example, when a memory address is provided, the WL driver 304 can activate the word-line of the memory cell array 312 corresponding to that address. This activation connects a row of memory cells (e.g., SRAM cells), allowing data to be transferred into or out of the array using corresponding bit lines. In one example, during a read operation, the WL driver 304 can receive a read address and of a location in memory of the memory cell array 312, and activate the corresponding word line, causing the memory cell array 312 to provide data stored in the cells of that word-line the memory output data W.

The multiplier device 314 can may be similar to, and include any of the components, structure, or functionality of, the multiplier device 114 and/or the mantissa shift block 116 described in connection with FIG. 1. The multiplier 314 may operate on floating point values, integer values, or both. The multiplier 314 may can receive the input data XIN via the input flip-flops 306, and data retrieved from the memory cell array 312 and generate a product that is provided to the output flip-flops 316. Each of the input flip-flops 306 and the output flip-flops 316 may include any number of flip-flop circuits to carry the bits of the input data XIN and bits of output data Q generated by the multiplier 314, respectively. The input flip-flops 306 and the output flip-flops 316 may be edge-activated devices on the same or different clock domains.

The control circuit 308 may include any number of circuits or logic gates to implement any of the zero-skipping functionality described herein. For example, the controller 308 may include the one or more first logic devices 104 and the second logic device 108 to determine that all of the bits of the input data XIN are in the first logic state, and provide the CIM_EN_DFF signal to deactivate one or more components (e.g., circuits of the WL driver 304, the input flip-flops 306, the multiplier 314, the output flip-flops 316, etc.). The CIM_EN_DFF may be an enable signal similar to the CIM_EN signal described in connection with FIG. 1. For example, the controller 308 can set the CIM_EN_DFF signal to the first logic state when all input bits of the input data XIN are in the first logic state, as described herein.

The CIM_EN_DFF signal is provided as an enable signal to various circuitry of the WL driver 304. For example, the CIM_EN_DFF signal can be provided as an enable signal to one or more flip-flops that capture an address of for the WL driver 304. The CIM_EN_DFF signal, when in the first logic state, may also disable other circuitry, logic gates, or devices included in the WL driver 304. The CIM_EN_DFF signal, when in the first logic state, can disable the input flip-flops 306, preventing said devices from expending power by changing state in response to a corresponding clock edge. The CIM_EN_DFF signal, when in the first logic state, can disable one or more logic gates, circuits, of the multiplier 314, preventing power consumption by foregoing multiplication operations for one or more clock cycles.

The CIM_EN_DFF signal, when in the first logic state, can also disable the output flip-flops 316, preventing said devices from expending power by changing state in response to a changing clock edge. In some implementations, the CIM_EN_DFF signal, when in the first logic state, can disable one or more circuits or logic gates of the controller 308, preventing unneeded power consumption and effectively “skipping the cycle” when all bits of the input data XIN are in the first logic state. In some implementations, the CIM_EN_DFF signal can be provided as input to one or more logic gates (e.g., the one or more second logic devices 110 of FIG. 1) that automatically set all M+1 bits of the output data Q to zero, as described herein.

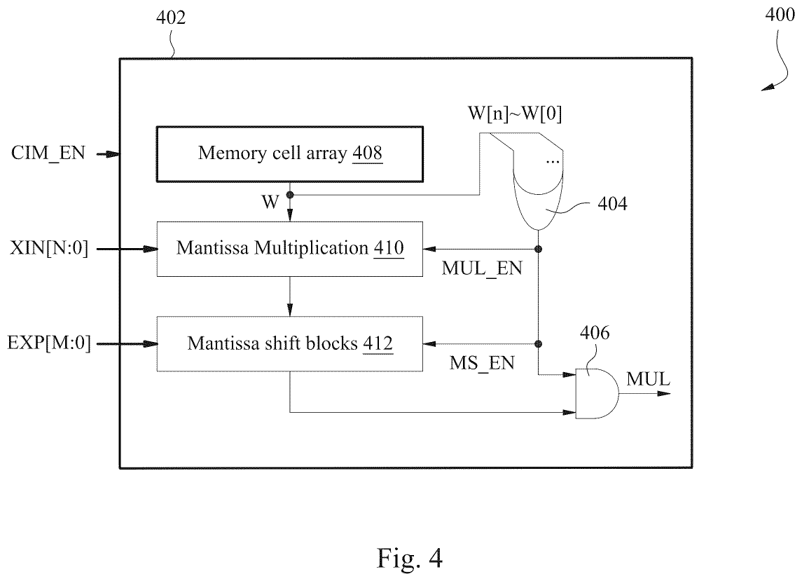

Referring to FIG. 4, illustrated is an example diagram 400 of a CIM circuit 402 that implements zero-skipping for memory output data W, in accordance with some embodiments of the present disclosure. Various embodiments of the circuits and logic gates that implement the CIM circuit 402 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 402 can be similar to, and include any of the structure, components, or functionality of the CIM circuit 102 described in connection with FIG. 1. For example, the memory cell array 408 can be similar to the memory circuit 112, the mantissa multiplication circuit 410 can be similar to the multiplier device 114, and the mantissa shift blocks 412 can be similar to the mantissa shift circuit 116. The example CIM circuit 402 can be utilized to perform multiplication operations on floating point values (e.g., the N+1 bits of input data XIN represent a mantissa of a floating point number, the M+1 bits of the input data exponent EXP represent the exponent of the floating point number). Likewise, the memory cell array 408 can provide the memory bits W that represent a second floating point number.

As shown, the mantissa multiplication circuit 410 includes an enable input MUL_EN that, when activated (e.g., receives an input in the second logic state, a logic high, logic one) causes the mantissa multiplication circuit 410 to be enabled. If the MUL_EN input is deactivated (e.g., receives an input in the first logic state, a logic low, logic zero), the mantissa multiplication circuit 410 is disabled. The mantissa shift blocks 412 includes an enable input MS_EN that, when activated (e.g., receives an input in the second logic state, a logic high, logic one) causes the mantissa shift blocks 412 to be enabled. If the MS_EN input is deactivated (e.g., receives an input in the first logic state, a logic low, logic zero), the mantissa shift blocks 412 is disabled.

The CIM circuit 402 is shown as including one or more first logic devices 404, which may be similar to the one or more first logic devices 104 of FIG. 1. In this example, the one or more first logic devices 404 are shown as implementing an n+1 input OR gate, which receives all n+1 bits of the memory output data W, as shown. The one or more first logic devices 404 therefore generate an output having the first logic state (e.g., logic low, logic zero) when all bits of the memory output data W are in the first logic state, and generate an output having the second logic state when any of the memory output bits W are in the second logic state. Therefore, when the memory output bits represent a value of “0,” both the mantissa multiplication circuit 410 and the mantissa shift blocks 412 are disabled, as described herein.

To control the output data MUL, the output of the one or more first logic devices 404 is provided as input to one or more second logic devices 406, which may be similar to the one or more third logic devices 110 described in connection with FIG. 1. In this example, the one or more second logic devices 406 include one or more logic AND gates. In some implementations, the one or more second logic devices 406 each receive the output of the one or more first logic devices 404 and a respective output bit of data produced by the mantissa shift blocks 412. The output of the one or more first logic devices 404, which operates as a zero-detection signal, is used by the one or more second logic devices 406 to generate output data MUL.

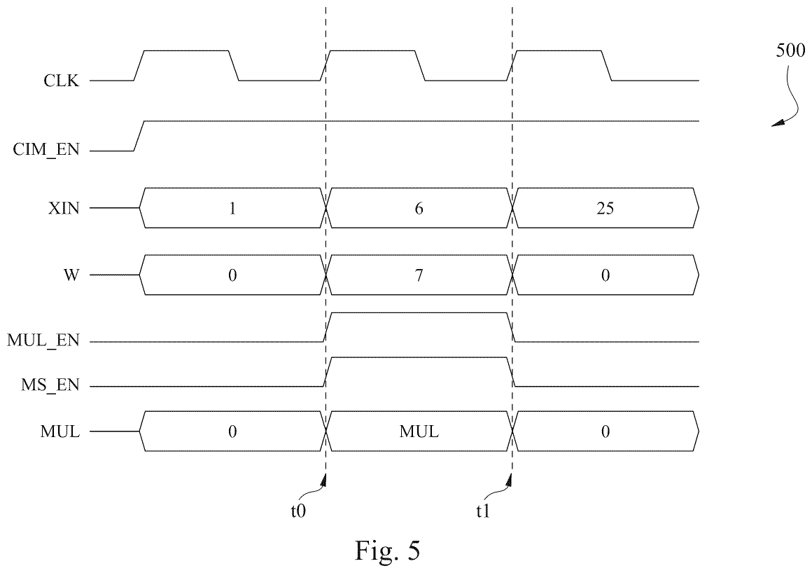

When the zero-detection signal is in the first logic state (e.g., logic low, logic zero), which indicates that all bits of the memory output data W are in the first logic state, the one or more second logic devices 406 cause each bit of the output data MUL to be in the first logic state. This effectively disables the CIM circuit 402 while setting the output data MUL for the circuit to be in the first logic state, using the one or more second logic devices 406 to bypass the CIM circuit 402 to produce each bit of the output data MUL. If the zero-detection signal is in the second logic state (e.g., logic high, logic one), the one or more second logic devices 406 cause each bit of the output data MUL to have the state of the corresponding bit of the output of the mantissa shift blocks 412. Example waveforms showing the operation of the CIM circuit 402 in connection with the one or more first logic devices 404 and the one or more second logic devices 406 is shown in FIG. 5.

Referring to FIG. 5, illustrated are example waveforms 500 of signals that propagate through the example CIM circuit 402 shown in FIG. 4, in accordance with some embodiments of the present disclosure. As shown, in this example, an input clock signal CLK continuously alternates and is unaffected by the logic state of the output memory data W. Likewise, the enable signal for the CIM circuit, CIM_EN, remains in the second logic state (e.g., logic high, logic one) throughout the operation of the circuit. As shown, before time t0, the memory output data W is equal to zero (e.g., all bits in the first logic state, logic low, logic zero). As a result, the one or more first logic devices 404 disable the MUL_EN and MS_EN inputs of the mantissa multiplication circuit 410 and the mantissa shift blocks 412, respectively. Likewise, the output data MUL, generated by the one or more second logic devices 406, are set to the first logic state (all bits set to zero).

As shown, after time t0 occurs, the memory output data W has changed to a non-zero value (e.g., not all bits in the first logic state), shown here as the value of “7.” As a result, the one or more first logic devices 404 generate the output enable signal for the MUL_EN and MS_EN inputs in the second logic state, causing the mantissa multiplication circuit 410 and the mantissa shift blocks 412, respectively, to be enabled and generate the output data MUL. The output data MUL is equal to the product of the input data XIN and the memory output data W. The product MUL is generated by the one or more second logic devices 406, as described herein. At time t1, the memory output data W changes back to the zero value, and the CIM circuit 402 is disabled as described herein.

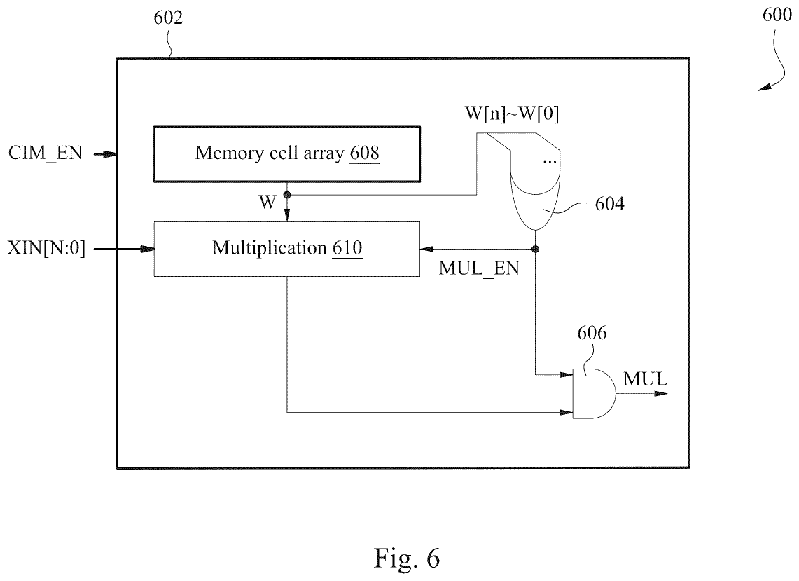

Referring to FIG. 6, illustrated is a diagram 600 of an example CIM multiplication circuit 602 that implements zero-skipping for memory output data W, in accordance with some embodiments of the present disclosure. Various embodiments of the circuits and logic gates that implement the CIM circuit 602 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 602 can be similar to, and include any of the structure, components, or functionality of the CIM circuit 102 described in connection with FIG. 1 or the CIM circuit 402 described in connection with FIG. 4. For example, the memory cell array 608 can be similar to the memory circuit 112 or the memory cell array 408 and the multiplication circuit 610 can be similar to the multiplier device 114. The example CIM circuit 602 can be utilized to perform multiplication operations on integer values (e.g., the N+1 bits of input data XIN represent an integer number). Likewise, the memory cell array 608 can provide the memory bits W that represent a second floating point number.

As shown, the multiplication circuit 610 includes an enable input MUL_EN that, when activated (e.g., receives an input in the second logic state, a logic high, logic one) causes the mantissa multiplication circuit 610 to be enabled. If the MUL_EN input is deactivated (e.g., receives an input in the first logic state, a logic low, logic zero), the multiplication circuit 610 is disabled. When enabled, the multiplication circuit 610 generates a product by performing binary multiplication between the memory output bits W and the input data XIN, as described herein.

The CIM circuit 602 is shown as including one or more first logic devices 604, which may be similar to the one or more first logic devices 104 of FIG. 1 or the one or more first logic devices 404 of FIG. 4. In this example, the one or more first logic devices 604 are shown as implementing an n+1 input OR gate, which receives all n+1 bits of the memory output data W, as shown. The one or more first logic devices 604 therefore generate an output having the first logic state (e.g., logic low, logic zero) when all bits of the memory output data W are in the first logic state, and generate an output having the second logic state when any of the memory output bits W are in the second logic state. Therefore, when the memory output bits W represent a value of “0,” the multiplication circuit 610 is disabled.

To control the output data MUL, the output of the one or more first logic devices 604 is provided as input to one or more second logic devices 606, which may be similar to the one or more third logic devices 110 described in connection with FIG. 1 or the one or more second logic devices 406 described in connection with FIG. 4. In this example, the one or more second logic devices 606 include one or more logic AND gates. In some implementations, the one or more second logic devices 606 each receive the output of the one or more first logic devices 604 and a respective output bit of data produced by the multiplication circuit 610. The output of the one or more first logic devices 604, which operates as a zero detection signal, is used by the one or more second logic devices 606 to generate output data MUL.

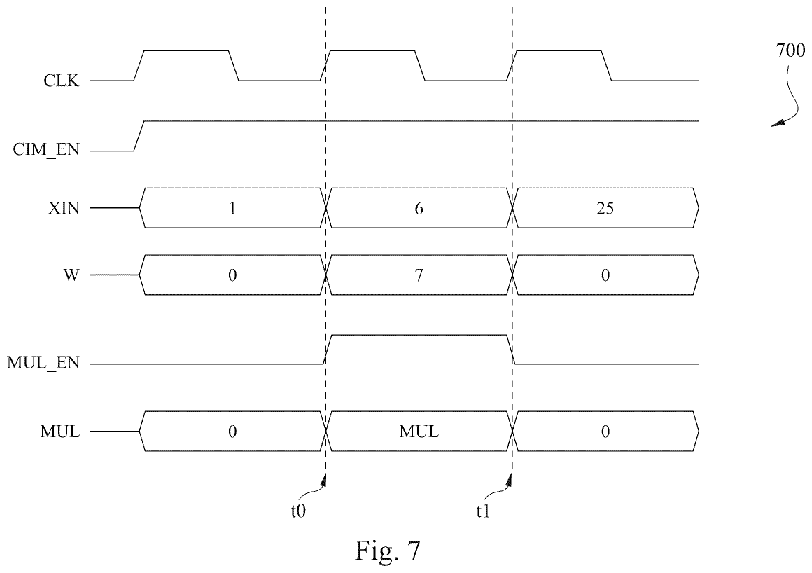

When the zero-detection signal is in the first logic state (e.g., logic low, logic zero), which indicates that all bits of the memory output data W are in the first logic state, the one or more second logic devices 606 cause each bit of the output data MUL to be in the first logic state. This effectively disables the CIM circuit 602 while setting the output data MUL for the circuit to be in the first logic state, using the one or more second logic devices 606 to bypass the CIM circuit 602 to produce each bit of the output data MUL. If the zero-detection signal is in the second logic state (e.g., logic high, logic one), the one or more second logic devices 606 cause each bit of the output data MUL to have the state of the corresponding bit of the output of the multiplication circuit 610. Example waveforms showing the operation of the CIM circuit 602 in connection with the one or more first logic devices 604 and the one or more second logic devices 606 is shown in FIG. 7.

Referring to FIG. 7, illustrated are example waveforms 700 of signals that propagate through the example CIM circuit shown in FIG. 6, in accordance with some embodiments of the present disclosure. As shown, in this example, an input clock signal CLK continuously alternates and is unaffected by the logic state of the output memory data W. Likewise, the enable signal for the CIM circuit, CIM_EN, remains in the second logic state (e.g., logic high, logic one) throughout the operation of the circuit. As shown, before time t0, the memory output data W is equal to zero (e.g., all bits in the first logic state, logic low, logic zero). As a result, the one or more first logic devices 604 disable the MUL_EN input of the multiplication circuit 610. Likewise, the output data MUL, generated by the one or more second logic devices 606, are set to the first logic state (all bits set to zero).

As shown, after time t0 occurs, the memory output data W has changed to a non-zero value (e.g., not all bits in the first logic state), shown here as the value of “7.” As a result, the one or more first logic devices 604 generate the output enable signal for the MUL_EN input in the second logic state, causing the multiplication circuit 610 to be enabled and to generate the output data MUL. The output data MUL is equal to the product of the input data XIN and the memory output data W. The product MUL is generated by the one or more second logic devices 606, as described herein. At time t1, the memory output data W changes back to the zero value, and the CIM circuit 602 is disabled as described herein.

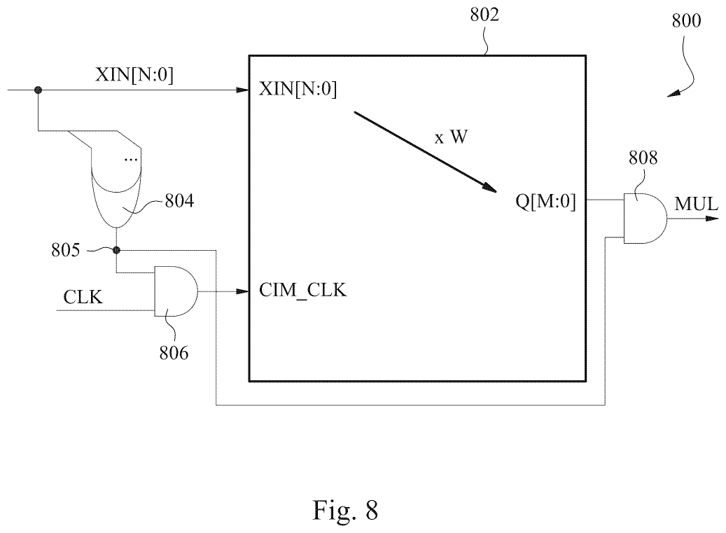

Referring to FIG. 8, illustrated is an example CIM multiplication circuit 802 that implements zero-skipping via gating of a clock signal CLK, in accordance with some embodiments of the present disclosure. Various embodiments of the circuits and logic gates that implement the CIM circuit 802 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 802 can be similar to, and include any of the structure, components, or functionality of the CIM circuit 102 described in connection with FIG. 1, the CIM circuit 402 described in connection with FIG. 4, or the CIM circuit 602 described in connection with FIG. 6. For example, the CIM circuit 802 may include a memory cell similar to the memory circuit 112, the memory cell array 408, or the memory cell array 608. The CIM circuit 802 can include a multiplication circuit for floating point and/or integer multiplication, similar to the multiplier device 114. The CIM circuit 802 can therefore be utilized to perform multiplication operations on integer values (e.g., the N+1 bits of input data XIN represent an integer number). In some implementations, when implementing floating point multiplication, the CIM circuit 802 can include a mantissa shift circuit, such as the mantissa shift circuit 116 or the mantissa shift blocks 412.

The CIM circuit 802 is shown as being coupled to one or more first logic devices 804, which may be similar to the one or more first logic devices 104 of FIG. 1 or the one or more first logic devices 404 of FIG. 4. In this example, the one or more first logic devices 804 are shown as implementing an N+1 input OR gate, which receives all N+1 bits of the input data XIN, as shown. The one or more first logic devices 804 therefore generate a zero detection output 805 (sometimes referred to as a “zero detection signal 805”) having the first logic state (e.g., logic low, logic zero) when all N+1 bits of the input data XIN are in the first logic state, and generate the zero detection output 805 having the second logic state when any of the input data XIN bits are in the second logic state.

As shown, the CIM circuit 802 is shown as being coupled to a second logic device 806, which may be similar to the second logic device 108 of FIG. 1. In this example, the second logic device 806 is implemented as a logic AND gate. The second logic device 806 is shown as receiving the zero-detection output 805 and an input clock signal CLK for the CIM circuit 802. The clock signal may be a clock signal to which one or more components (e.g., the memory array, control circuitry, flip-flops, the multiplication circuit, etc.) are synchronized. When the CIM_CLK signal is disabled (e.g., the zero-detection signal 805 is in the first logic state), the states of the logic devices in the CIM circuit 802 do not change, thereby conserving power consumption. The second logic device 806 generates an output clock signal CIM_CLK that is provided to a clock input of the CIM circuit 802. In this example, the zero-detection signal 805 is in the second logic state (e.g., logic high, logic one, etc.), the clock signal CIM_CLK is provided in the same logic state as the input clock signal CLK, and the CIM circuit 802 is enabled and operates as described herein.

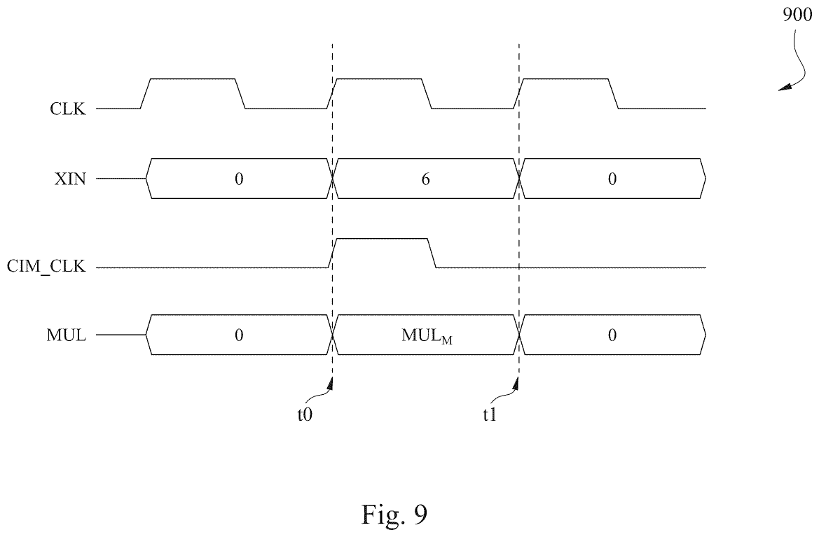

To control the output data, the zero-detection signal 805 is provided as input to one or more third logic devices 808, which may be similar to the one or more third logic devices 110 of FIG. 1. In this example, the one or more third logic devices 808 include one or more logic AND gates. In some implementations, the one or more third logic devices 808 each receive the zero-detection signal 805 and a respective output bit of the output data Q[M:0] of the CIM circuit 802 (e.g., a product output from multiplication operations between the input data XIN and memory output data W). The zero-detection signal 805, which operates as a zero detection signal, is used by the one or more third logic devices 808 to generate output data MUL. The output data MUL can include the same number of bits as the output data Q[M:0] (e.g., M+1 bits). When the zero-detection signal 805 is in the first logic state (e.g., logic low, logic zero), which indicates that the input data XIN is all in the first logic state, the one or more third logic devices 808 causes each bit of the output data MUL to be in the first logic state. This effectively disables the CIM circuit 802 while setting the output data MUL for the circuit to be in the first logic state, using the one or more third logic devices 808 to bypass the CIM circuit 802 to produce each bit of the output data MUL. Example waveforms showing the operation of the CIM circuit 802 in connection with the one or more first logic devices 804, the second logic device 806, and the one or more third logic devices 808 is shown in FIG. 9.

Referring to FIG. 9 in the context of the components described in connection with FIG. 8, illustrated are example waveforms 200 of signals that propagate through the example CIM circuit 802 shown in FIG. 8, in accordance with some embodiments of the present disclosure. As shown, in this example, an input clock signal CLK continuously alternates and is unaffected by the logic state of the input data XIN. As shown, before time t0, the input data XIN is equal to zero (e.g., all bits in the first logic state, logic low, logic zero). As a result, the one or more first logic devices 804 and the second logic device 805 generate the output clock signal CIM_CLK in the first logic state (e.g., logic low, logic zero), effectively preventing state changes in the CIM circuit 802. Likewise, the output data MUL, generated by the one or more third logic devices 808, is in the first logic state (all bits set to zero).

As shown, after time t0 occurs, the input data XIN has changed to a non-zero value (e.g., not all bits in the first logic state), shown here as the value of “6.” As a result, the one or more first logic devices 804 and the second logic device 806 generate the output clock signal CIM_CLK having the same logic state as the input clock signal CLK, as shown, effectively enabling the components of the CIM circuit 802. The output data MUL updated and set equal to the product of the input data XIN and memory output data W, as described herein. In this example, the product is shown as “MUL_{M},” and is generated by the one or more third logic devices 808, as described herein. At time t1, the input data XIN changes back to the zero value, and the CIM_CLK signal is disabled as described herein.

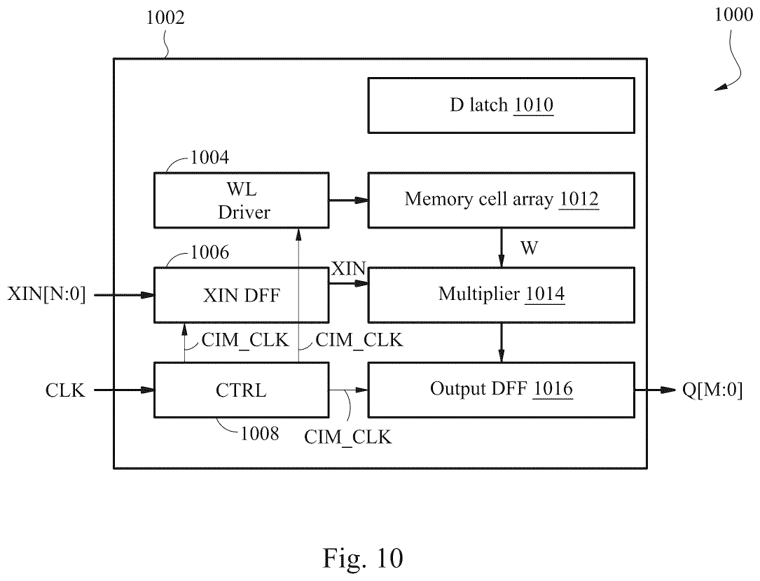

Referring to FIG. 10, illustrated is another example processing system 1000 that implements zero-skipping using a controller 1008 and clock gating, in accordance with some embodiments of the present disclosure. Various embodiments of the circuits and logic gates that implement the processing system 1000 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 1002 of the processing system 1000 can be similar to, and can include any of the structure, components, or functionality of, the CIM circuit 302 of the processing system 300 described in connection with FIG. 3. For example, the controller 1008 may be similar to the controller 308, the data input latches 1010 may be similar to the data input latches 310, the WL driver 1004 may be similar to the WL driver 304, the input flip-flops 1006 may be similar to the input flip-flops 306, the memory cell array 1012 may be similar to the memory cell array 312, the multiplier circuit 1014 may be similar to the multiplier circuit 314, and the output flip-flops 1016 may be similar to the output flip-flops 316 of FIG. 3.

The control circuit 1008 may include any number of circuits or logic gates to implement any of the zero-skipping functionality described herein. For example, the controller 1008 may include the one or more first logic devices 804 and the second logic device 806 to determine that all of the bits of the input data XIN are in the first logic state. The controller 1008 can receive the input clock signal CLK and provide the output clock signal CIM_CLK to deactivate one or more components (e.g., circuits of the WL driver 1004, the input flip-flops 1006, the output flip-flops 1016, etc.) of the CIM circuit 802. In some implementations, the CIM_CLK signal, when held in the first logic state, can deactivate the multiplier circuit 1014. The CIM_CLK may be the clock signal to which the components (e.g., the input flip-flops 1006, the address flip-flops or other circuits of the WL driver 1004, the multiplier circuit 1014, the output flip-flops 1016, etc.) are synchronized. When the CIM_CLK signal is held in a constant logic state, the state of the components do not update, and therefore power dissipation in said components is minimized.

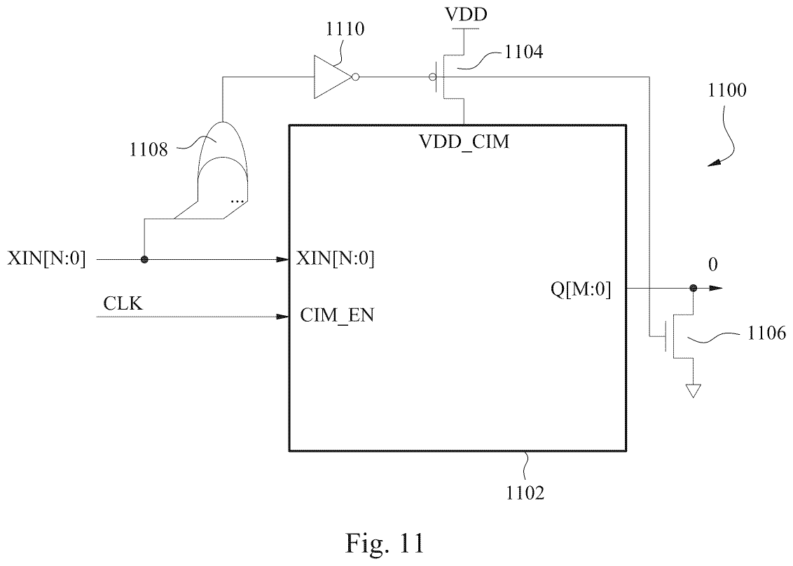

Referring to FIG. 11, illustrated is a diagram 1100 of an example CIM multiplication circuit 1102 that implements zero-skipping via gating of a power signal, in accordance with some embodiments of the present disclosure. Various embodiments of the circuits and logic gates that implement the CIM circuit 1002 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 1102 can be similar to, and include any of the structure, components, or functionality of the CIM circuit 102 described in connection with FIG. 1, the CIM circuit 402 described in connection with FIG. 4, the CIM circuit 602 described in connection with FIG. 6, or the CIM circuit 1102 described in connection with FIG. 11. For example, the CIM circuit 1102 may include a memory cell similar to the memory circuit 112, the memory cell array 408, or the memory cell array 608. The CIM circuit 1102 can include a multiplication circuit for floating point and/or integer multiplication, similar to the multiplier device 114. The CIM circuit 1102 can therefore be utilized to perform multiplication operations on integer values (e.g., the N+1 bits of input data XIN represent an integer number). In some implementations, when implementing floating point multiplication, the CIM circuit 1102 can include a mantissa shift circuit, such as the mantissa shift circuit 116 or the mantissa shift blocks 412.

The CIM circuit 1102 is shown as being coupled to one or more first logic devices 1104, which may be similar to the one or more first logic devices 104 of FIG. 1, the one or more first logic devices 404 of FIG. 4, or the one or more first logic devices 604 of FIG. 6. In this example, the one or more first logic devices 1104 are shown as implementing an N+1 input OR gate, which receives all N+1 bits of the input data XIN, as shown. The one or more first logic devices 1104 therefore generate a zero-detection output having the first logic state (e.g., logic low, logic zero) when all N+1 bits of the input data XIN are in the first logic state, and generate the zero detection output having the second logic state when any of the input data XIN bits are in the second logic state.

As shown, in this example, the zero-detection signal is provided as input to the inverter 1110, which logically inverts the zero detection signal generated by the one or more first logic devices 1108. The output of the inverter 1110 is provided as input to a gate terminal of one or more first transistors 1104. In this example, the one or more first transistors 1104 include P-type transistors that provide power to one or more components of the CIM circuit 1102. In some implementations, the one or more first transistors 1104 may be N-type transistors that couple one or more components of the CIM circuit 1102 to ground. In such implementations, the inverter 1110 may not necessarily be included, or may be coupled to a second inverter to buffer the zero-detection signal from the one or more first logic devices 1108.

As shown, in this example, each of the one or more first transistors 1104 receive power (shown here as VDD) at a first source/drain terminal and provide a power signal (shown here as VDD_CIM) to one or more components of the CIM circuit 1102 at a second source/drain terminal. In some implementations, the memory array of the CIM circuit 1102 may receive power directly from VDD or another power circuit, such that when power is disabled the contents of the memory array are not lost. As described herein, when the input at the gate terminal of each of the one or more first transistors 1104 is in the first logic state, the one or more first transistors 1104 can provide the power signal VDD_CIM to the CIM circuit 1102. However, when all input bits XIN are in the first logic state, the inverter 1110 provides a signal having the second logic state (e.g., logic high, logic one) to the one or more first transistors 1104, turning them off and preventing them from conducting. This removes the power signal VDD_CIM from one or more components of the CIM circuit 1102, thereby disabling them.

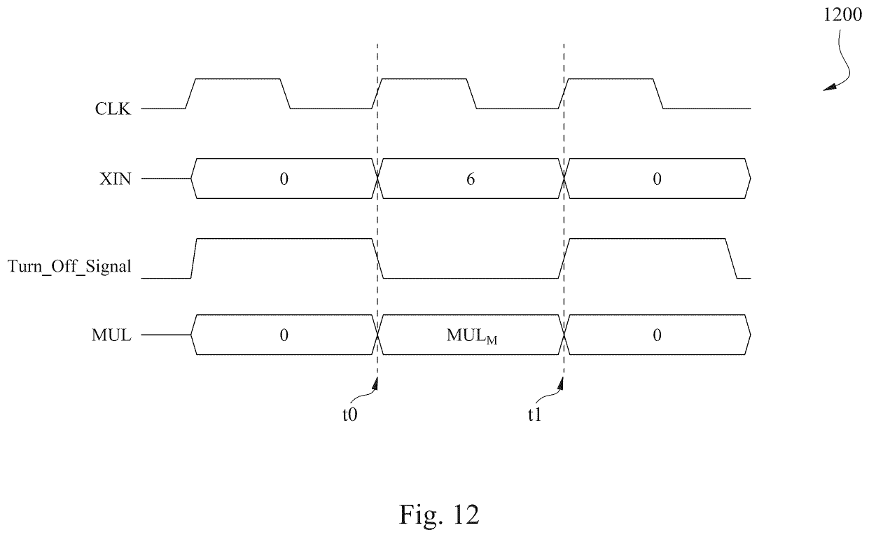

The signal generated by the inverter 1110 is provided to gate terminal(s) of one or more second transistors 1106. In this example, the second transistor is an N-type transistor. The one or more second transistors 1106 can include a first source/drain terminal coupled to the M+1 output bit lines Q[M:0]. When the signal generated by the inverter 1110 is in the first logic state (e.g., logic low, logic zero), the one or more second transistors 1106 are turned off and do not conduct, and the output bit lines Q[M:0] retain their logic state. When the signal generated by the inverter 1110 is in the second logic state (e.g., logic high, logic one), the one or more second transistors 1106 are turned on and conduct, causing the output bit lines Q[M:0] to be pulled to ground (e.g., the first logic state, logic low, logic zero). This provides a zero output on each of the output bit lines Q[M:0], effectively bypassing the CIM circuit 1102. Example waveforms showing the operation of the CIM circuit 1102 in connection with the one or more first logic devices 1108, the inverter 1110, the one or more first transistors 1104, and the one or more second transistors 1106 is shown in FIG. 12.

Referring to FIG. 12, illustrated are example waveforms 1200 of signals that propagate through the example CIM circuit 1102 shown in FIG. 11, in accordance with some embodiments of the present disclosure. As shown, in this example, an input clock signal CLK continuously alternates and is unaffected by the logic state of the input data XIN. As shown, before time t0, the input data XIN is equal to zero (e.g., all bits in the first logic state, logic low, logic zero). As a result, the one or more first logic devices 1108 and the inverter 1110 produce signal(s) (shown here as the “Turn_Off_Signal”) that turns off power to one or more components of the CIM circuit 1102. Additionally, the one or more second transistors 1106 are turned on and conducting, causing the output data MUL to be set to zero.

As shown, after time t0 occurs, the input data XIN has changed to a non-zero value (e.g., not all bits in the first logic state), shown here as the value of “6.” As a result, the one or more first logic devices 1108 and the inverter 1110 cause the Turn_Off_Signal to be in the first logic state (e.g., logic low, logic zero), which turns on the one or more first transistors 1104 and turns off the one or more second transistors 1106. This causes power to be supplied to the components of the CIM circuit 1102, and enables the output bits Q[M:0] (the output data MUL) to be set to the product generated by the components of the CIM circuit 1102. In this example, the product is shown as “MUL_{M}.” At time t1, the input data XIN changes back to the zero value, and the Turn_Off_Signal removes power from one or more components of the CIM circuit 1102, as described herein.

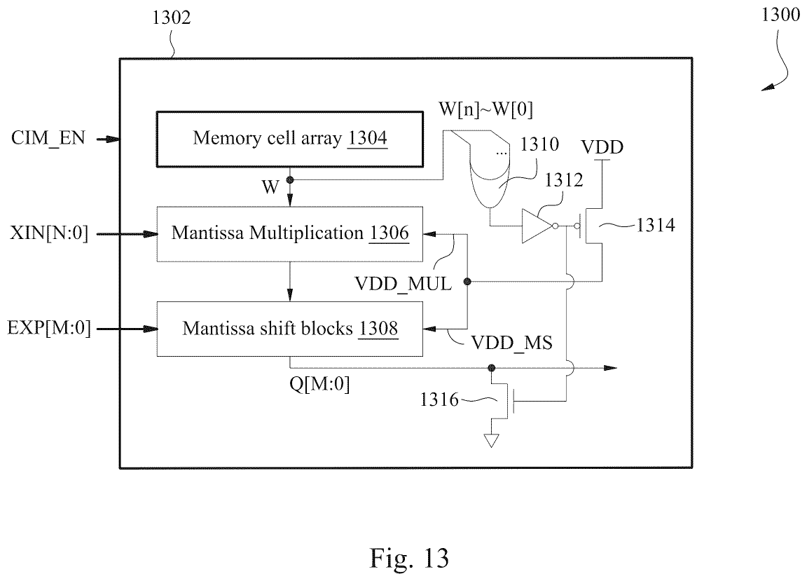

Referring to FIG. 13, illustrated is an example CIM multiplication circuit 1302 that implements zero-skipping via gating of a power signal based on memory output bits W, in accordance with some embodiments of the present disclosure. Various embodiments of the circuits and logic gates that implement the CIM circuit 1302 may include various transistors. The transistors described herein may have a certain type (n-type or p-type), but embodiments are not limited thereto. The transistors can be any suitable type of transistor including, but not limited to, MOSFETs, CMOS transistors, PMOS, NMOS, BJTs, high voltage transistors, high frequency transistors, PFETs/NFETs, FinFETs, planar MOS transistors with raised source/drains, nanosheet FETs, nanowire FETs, or the like.

The CIM circuit 1302 can be similar to, and include any of the structure, components, or functionality of the CIM circuit 102 described in connection with FIG. 1, the CIM circuit 402 described in connection with FIG. 4, or the CIM circuit 602 described in connection with FIG. 6. For example, the memory cell array 1304 can be similar to the memory circuit 112, the mantissa multiplication circuit 1306 can be similar to the multiplier device 114, and the mantissa shift blocks 1308 can be similar to the mantissa shift circuit 116. The example CIM circuit 1302 can be utilized to perform multiplication operations on floating point values (e.g., the N+1 bits of input data XIN represent a mantissa of a floating point number, the M+1 bits of the input data exponent EXP represent the exponent of the floating point number). Likewise, the memory cell array 1304 can provide the memory bits W that represent a second floating point number.

As shown, the mantissa multiplication circuit 1306 includes a power input VDD_MUL that receives power when the one or more first transistors 1314 are turned on and conducting. If the one or more first transistors 1314 are turned off and not conducting, the power input VDD_MUL does not receive power and the mantissa multiplication circuit 1306 does not perform multiplication operations. The mantissa shift blocks 1308 includes a power input VDD_MS that receives power when the one or more first transistors 1314 are turned on and conducting. If the one or more first transistors 1314 are turned off and not conducting, the power input VDD_MS does not receive power and the mantissa shift blocks 1308 are not used to perform floating point multiplication operations.

The CIM circuit 1302 is shown as including one or more first logic devices 1310, which may be similar to the one or more first logic devices 104 of FIG. 1, the one or more first logic devices 404 of FIG. 4, or the one or more first logic devices 604 of FIG. 6. In this example, the one or more first logic devices 1310 are shown as implementing an n+1 input OR gate, which receives all n+1 bits of the memory output data W, as shown. The one or more first logic devices 1310 therefore generate a zero-detection output having the first logic state (e.g., logic low, logic zero) when all n+1 bits of the memory output data W are in the first logic state, and generate the zero detection output having the second logic state when any of the memory output data W are in the second logic state.

As shown, in this example, the zero-detection signal is provided as input to the inverter 1312, which logically inverts the zero detection signal generated by the one or more first logic devices 1310. The output of the inverter 1312 is provided as input to a gate terminal of the one or more first transistors 1314. In this example, the one or more first transistors 1310 include P-type transistors that provide power to the mantissa multiplication circuit 1306 and the mantissa shift blocks 1308. In some implementations, the one or more first transistors 1314 may be N-type transistors that couple the mantissa multiplication circuit 1306 and the mantissa shift blocks 1308 to ground. In such implementations, the inverter 1312 may not necessarily be included, or may be coupled to a second inverter to buffer the zero-detection signal from the one or more first logic devices 1308.

As shown, in this example, each of the one or more first transistors 1314 receive power (shown here as VDD) at a first source/drain terminal and provide a power signal to the power inputs VDD_MUL and VDD_MS at a second source/drain terminal. As shown, the memory array 1304 can receive power directly from VDD or another power circuit, such that when power is disabled the contents of the memory array are not lost. As described herein, when the input at the gate terminal of each of the one or more first transistors 1314 is in the first logic state, the one or more first transistors 1314 can provide power to the power inputs VDD_MUL and VDD_MS. However, when all memory output data W bits are in the first logic state, the inverter 1312 provides a signal having the second logic state (e.g., logic high, logic one) to the one or more first transistors 1310, turning them off and preventing them from conducting. This removes power from the power inputs VDD_MUL and VDD_MS, disabling both the mantissa multiplication circuit 1306 and the mantissa shift blocks 1308.

The signal generated by the inverter 1312 is provided to gate terminal(s) of one or more second transistors 1316. In this example, the second transistor is an N-type transistor. The one or more second transistors 1316 can include a first source/drain terminal coupled to the M+1 output bit lines Q[M:0] of the mantissa shift blocks 1308. When the signal generated by the inverter 1312 is in the first logic state (e.g., logic low, logic zero), the one or more second transistors 1316 are turned off and do not conduct, and the output bit lines Q[M:0] retain their logic state. When the signal generated by the inverter 1312 is in the second logic state (e.g., logic high, logic one), the one or more second transistors 1316 are turned on and conduct, causing the output bit lines Q[M:0] to be pulled to ground (e.g., the first logic state, logic low, logic zero). This provides a zero output on each of the output bit lines Q[M:0], effectively bypassing operations of the CIM circuit 1302.

In addition, various embodiments of the present disclosure may be combined without limitation. For example, implementations where zero detection signals are provided based on zero input data XIN may be combined with implementations where zero detection signals are provided based on zero memory output data W. Doing so reduces the overall power consumption of the CIM devices without impacting the accuracy of calculations, thereby improving the performance of the device.

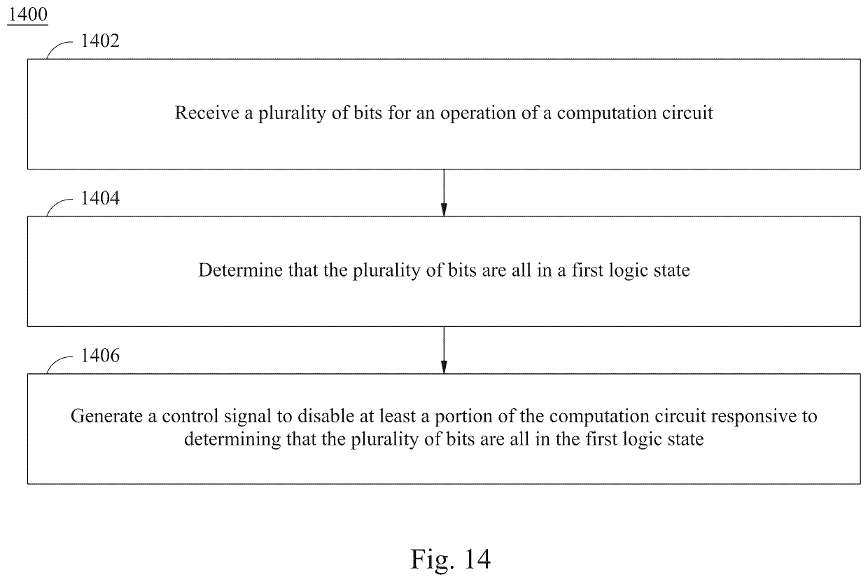

FIG. 14 illustrates a flowchart of an example method 1400 to operate the CIM circuits described here, in accordance with some embodiments of the present disclosure. The method 1400 may be used to selectively disable one or more components of CIM circuits or processing systems (e.g., the CIM circuit 102, the processing system 300, the CIM circuit 402, the CIM circuit 602, the CIM circuit 802, the processing circuit 1002, the CIM circuit 1102, the CIM circuit 1302, etc.) in response to an operand of said devices being equal to zero (e.g., in a first logic state). Accordingly, it is understood that additional operations may be provided before, during, and after the method 1400 of FIG. 14, and that some other operations may only be briefly described herein.

In brief overview, the method 1400 starts with operation 1402 of the receiving a plurality of bits (e.g., the input data XIN or the memory output data W) for an operation (e.g., integer multiplication or floating-point multiplication) of a computation circuit (e.g., a floating point or integer multiplication circuit). The method 1400 proceeds with operation 1404 of determining that the plurality of bits are all in a first logic state (e.g., logic low, logic zero). The method 1400 concludes with operation 1406 of generating a control signal (e.g., a zero-detection signal) to disable at least a portion of the computation circuit responsive to determining that the plurality of bits are all in the first logic state. The method 1400 may be performed using the various components described herein, and in some implementations may be performing using a controller (e.g., the controller 308, the controller 1008, any other combination of logic devices, circuits, or transistors, etc.).

Referring to operation 1402, a plurality of bits (e.g., the input data XIN or memory output data W) for an operation of a computation circuit are received. The plurality of bits may be provided as input to the computation circuit or provided from a memory of the computation circuit, for example, in response to a read operation. The plurality of bits may be provided as input via another circuit as an operand for an integer for floating-point multiplication operation. The bits may be provided via one or more flip-flops or other logic devices, and may be provided as input to one or more zero detection devices (e.g., multiple input OR gates, etc.).

Referring to operation 1404, it is determined that each of the plurality of bits are in a first logic state. To do so, logic devices (e.g., the one or more first logic devices 104, the one or more first logic devices 404, the one or more first logic devices 604, the one or more first logic devices 804, the one or more first logic devices 1108, etc.) can receive the plurality of bits as input and generate a zero-detection signal. For example, one or more logical OR gates may be provided that implement an OR device that receives all of the plurality of bits and generates a single output. When any of the plurality of bits is in a logic high state, the output of the OR device is a logic high (e.g., indicating that no zero is present). When all of the plurality bits are in a logic low state, the output of the OR device is logic low (e.g., the first logic state), indicating that the plurality of bits are all logic low or logic zero. Other types of logic devices, including inverse OR (NOR) may be utilized to generate the zero-detection signal.

Referring to operation 1406, a control signal is generated to disable at least a portion of the computation circuit responsive to determining that each of the plurality of bits are in the first logic state. In some implementations, the control signal is the zero-detection signal, and can be provided as input to an enable input of one or more components (e.g., a multiplier, a mantissa shift block, etc.) of the computation circuit. In some implementations, the control signal can be provided as input to one or more additional logic devices, that cause the state of a clock signal for one or more components of the computation circuit to remain in a first or second logic state.

In some implementations, the control signal can disable power for one or more components of the computation circuit. For example, the control signal may be provided as input to gate terminal(s) one or more transistors (e.g., the one or more first transistors 1104, the one or more first transistors 1314) that provide power to the one or more components of the computation circuit when the one or more transistors are turned on and conducting. The control signal, when indicating that the plurality of bits are all in the first logic state, can cause the one or more transistors to be turned off and stop conducting, thereby removing power from one or more components of the computation circuit.

In one aspect of the present disclosure, a system is disclosed. The system includes a computation circuit, a memory array, and a controller. The controller can determine that one or more input data bits to the computation circuit or one or more memory bits provided from the memory array are all in a first logic state. The controller can, in response to determining that the one or more input data bits or the one or more memory bits are all in the first logic state, generate a control signal to disable at least one component of the computation circuit.

In another aspect of the present disclosure, a circuit is disclosed. The circuit includes a computation device, a first logic gate that receives a plurality of bits for the computation device and generates a control signal for the computation circuit, and a second logic gate that receives the control signal and at least one output of the computation device and generates at least one output bit for the circuit.

In yet another aspect of the present disclosure, a method is disclosed. The method includes receiving, by a controller, a plurality of bits for an operation of a computation circuit. The method includes determining, by the controller, that the plurality of bits are all in a first logic state. The method includes generating, by the controller, a control signal to disable at least a portion of the computation circuit responsive to determining that the plurality of bits are all in the first logic state.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A controller device, comprising:
one or more logic gates configured to:
receive a set of bits provided by a memory array, and
generate an output based on the set of bits; and
a transistor configured to:
receive the output generated using the one or more logic gates, and
selectively disable a computation circuit based on the output.

2. The controller device of claim 1, wherein the one or more logic gates are configured to generate the output in a first logic state based on the set of bits being in the first logic state.

3. The controller device of claim 1, wherein the one or more logic gates comprise an OR gate and a NOT gate.

4. The controller device of claim 1, wherein a first source/drain terminal of the transistor is coupled to a supply voltage and a second source/drain terminal of the transistor is coupled to a power terminal of the computation circuit.

5. The controller device of claim 4, wherein a gate terminal of the transistor receives the output generated by the one or more logic gates.

6. The controller device of claim 1, wherein the transistor is a p-type transistor.

7. The controller device of claim 1, wherein the transistor is configured to selectively disable a mantissa multiplication circuit and a mantissa shift circuit.

8. The controller device of claim 1, further comprising one or more second transistors configured to selectively cause a second output of the computation circuit to be in a logic low state based on the output of the one or more logic gates.

9. The controller device of claim 8, wherein the one or more second transistors each comprise a first source/drain terminal coupled to a ground voltage and a second source/drain terminal coupled to the second output of the computation circuit.

10. The controller device of claim 1, wherein the computation circuit generates a floating-point output.

11. A circuit, comprising:
a first logic gate configured to:
receive a set of bits provided by a memory array, and
generate an output based on the set of bits; and
a second logic gate configured to selectively disable a computation circuit based on the output of the first logic gate.

12. The circuit of claim 11, wherein the first logic gate comprises an OR gate.

13. The circuit of claim 11, wherein the second logic gate comprises an AND gate.

14. The circuit of claim 11, wherein the second logic gate receives a clock signal and provides an output clock signal to the computation circuit.

15. The circuit of claim 11, further comprising a third logic gate configured to receive a second output of the computation circuit.

16. The circuit of claim 15, wherein the third logic gate is further configured to receive the output of the first logic gate and provide an output signal, wherein the third logic gate selectively sets the output signal to a logic low value according to the output of the first logic gate.

17. The circuit of claim 11, wherein the set of bits is provided as input to the computation circuit.

18. A method, comprising:
receiving, by one or more logic gates, a set of bits;
generating, by the one or more logic gates, an output based on the set of bits; and
selectively disabling, by a transistor, power to a computation circuit based on the output.

19. The method of claim 18, wherein the set of bits is provided as input to the computation circuit or provided from a memory of the computation circuit.

20. The method of claim 18, further comprising:
selectively setting, by a second transistor, a second output of the computation circuit to a ground voltage based on the output of the one or more logic gates.
